(19) United States
(12) Patent Application Publication
(10) Pub. No.: US 2024/0128305 A1
(43) Pub. Date: Apr. 18, 2024

(54) LED PIXEL UNIT, DISPLAY PANEL AND DISPLAY SCREEN

(71) Applicant: Xiamen Extremely PQ Display Technology Co., Ltd., Xiamen (CN)

(72) Inventor: CHEN-KE HSU, Xiamen (CN)

(21) Appl. No.: 18/542,638

(22) Filed: Dec. 16, 2023

Related U.S. Application Data
(63) Continuation of application No. PCT/CN2022/071085, filed on Jan. 10, 2022.

(30) Foreign Application Priority Data
Dec. 24, 2021 (CN) 2021115991863

(51) Int. Cl. H01L 27/15; H01L 25/075; H01L 33/60

(52) U.S. Cl. CPC H01L 27/156; H01L 25/0756; H01L 33/60; H01L 27/14625

(57) ABSTRACT

A LED pixel unit, a display panel and a display screen are provided. The LED pixel unit includes: multiple micro-LEDs with different emission wavelengths and an optical module, the micro-LEDs are stacked to form a stacked structure, the stacked structure has a light-emitting surface, and the stacked structure is configured to emit, from the light-emitting surface, light emitted by the micro-LEDs at a first emission angle; the optical module is disposed above the light-emitting surface and at a predetermined distance from the light-emitting surface, and the optical module is configured to emit, at a second emission angle, the light emitted by the light-emitting surface. The light emitted by the micro-LEDs in the same pixel unit is all emitted from the same light-emitting surface, incident on the optical module at the same angle, and emitted from the optical module at the same angle, so that a dispersion phenomenon can be avoided.

### CROSS-REFERENCE TO RELATED APPLICATIONS

The invention is a continuation of International Application No. PCT/CN2022/071085, filed on Jan. 10, 2022. The international Application claims priority from Chinese patent application No. 202111599186.3, filed on Dec. 24, 2021. The entire contents of the above-mentioned applications are hereby incorporated herein by reference.

### TECHNICAL FIELD

The disclosure relates to the field of display technologies, and particularly to a light-emitting diode (LED) pixel unit, a display panel and a display screen.

### BACKGROUND

The micro light-emitting diode (micro-LED) display technology is a new generation of display technology, which mainly miniaturizes and matrixes traditional LEDs, so that a size of a single LED can be reduced to dozens of micrometers or even a few micrometers, and each LED pixel can be driven to emit light independently. Compared with traditional display devices, display devices made of micro-LEDs have advantages such as high contrast, fast response speed and low energy consumption.

A display device is made by horizontally laying red, green, and blue micro-LEDs on a two-dimensional plane, and each pixel unit includes red, green, and blue micro-LEDs. When applying the above display device to a projection product with small light-emitting angle or a display product with small visual angle, it is necessary to provide an optical module on a light-emitting side of the display device and use the optical module to reduce a light-emitting angle of each pixel unit. Since the red, green, and blue micro-LEDs are horizontally laid on the two-dimensional plane, emission angles of light emitted by the three micro-LEDs in the same pixel unit are inconsistent. After passing through the optical module, the emission angles of the light emitted by the three micro-LEDs still differ, resulting in a dispersion phenomenon caused by mixing of some light emitted from the micro-LEDs, which can easily cause color difference of a displayed image at different visual angles.

Therefore, how to provide a LED pixel unit, a display panel, and a display device to avoid the dispersion phenomenon in the LED pixel unit and to avoid the color difference at different visual angles caused by the dispersion becomes an urgent problem to be solved in this field.

### SUMMARY

A purpose of the disclosure is to provide a LED pixel unit, which makes light emitted by multiple micro-LEDs in a same LED pixel unit all be emitted from a same light-emitting surface, incident on an optical module at a same angle, and emitted from the optical module at a same angle, thereby avoiding the dispersion phenomenon and avoiding the problem that the LED pixel unit has color difference at different visual angles due to the dispersion phenomenon.

Another purpose of the disclosure is to provide a display panel and a display screen.

In a first aspect, the disclosure provides a LED pixel unit, including:
multiple micro-LEDs with different emission wavelengths, stacked to form a stacked structure; the stacked structure having a light-emitting surface, and the stacked structure being configured to emit, from the light-emitting surface, light emitted by the micro-LEDs at a first emission angle; and
an optical module, disposed above the light-emitting surface and at a predetermined distance from the light-emitting surface; a projection area of a vertical projection of the optical module being greater than or equal to a projection area of a vertical projection of the stacked structure; and the optical module being configured to emit, at a second emission angle, the light emitted by the light-emitting surface.

In an embodiment, a width of the stacked structure is d₁, a width of the optical module is d₂, a distance between the optical module and the light-emitting surface is d₃, and the first emission angle is A; and

$${d}_{1} \leq {d}_{2} \leq 2 {d}_{3} tan \frac{A}{2} , A \leq 130 ° .$$

In an embodiment, projection areas of vertical projections of the micro-LEDs are equal, and the micro-LEDs have same light-emitting axes.

In an embodiment, projection areas of vertical projections of the micro-LEDs are decreased, and the micro-LEDs have same light-emitting axes.

In an embodiment, projection areas of vertical projections of the micro-LEDs are decreased, and a light-emitting axis of the micro-LED at a side of the stacked structure facing away from the light-emitting surface coincides with a light-emitting axis of the micro-LED at a side of the stacked structure proximate to the light-emitting surface.

In an embodiment, a central axis of the optical module coincides with the light-emitting axes of the micro-LEDs.

In an embodiment, a central axis of the optical module coincides with the light-emitting axis of the micro-LED at the side of the stacked structure proximate to the light-emitting surface.

In an embodiment, an angle α₁ between a central axis of the optical module and light-emitting axes of the micro-LEDs is greater than 5°.

In an embodiment, a light-emitting angle α₂ of the LED pixel unit is less than or equal to 80°.

In an embodiment, the stacked structure includes, from bottom to top, a red LED chip, a green LED chip, and a blue LED chip.

In a second aspect, the disclosure provides a display panel, including: a substate and multiple pixel units disposed on the substrate; and each pixel unit is the LED pixel unit described above, the stacked structure is disposed on the substrate, and the optical module is disposed at a side of the stacked structure facing away from the substrate.

In an embodiment, a width of each pixel unit is d₄, and d₁≤d₂≤d₄.

In an embodiment, a central axis of the optical module is perpendicular to the substrate, and an angle between the stacked structure and the substrate is β₁, which is greater than 5°.

In an embodiment, a central axis of the optical module and a light-emitting axis of the stacked structure are both perpendicular to the substrate.

In a third aspect, the disclosure provides a display screen, including the display panel as described above.

Compared with the related art, the disclosure has at least the following beneficial effects.

(1) Micro-LEDs in a same LED pixel unit are stacked to form a stacked structure, so that light emitted by the micro-LEDs can all be emitted from a same light-emitting surface, incident on an optical module at a same angle, and emitted from the optical module at a same angle, which can avoid the dispersion phenomenon of the LED pixel unit, and avoid the problem that the LED pixel unit has color difference at different visual angles due to the dispersion phenomenon, and the effect is particularly obvious for LED pixel units with small light-emitting angles.

(2) A width of the stacked structure is d₁, a width of the optical module is d₂, a distance between the optical module and the light-emitting surface is d₃, a first emission angle is A, and

$${d}_{1} \leq {d}_{2} \leq 2 {d}_{3} tan \frac{A}{2} , A \leq 130 ° ,$$

thereby making the optical module cover a whole emission range of light emitted by the stacked structure, so as to adjust all light emitted by the stacked structure and make a light-emitting angle of the LED pixel unit less than or equal to 80°.

(3) The micro-LEDs have same light-emitting axes, and the light-emitting axes of the micro-LEDs coincide with a light-emitting axis of the stacked structure, thus ensuring the consistency of the light emitted by the micro-LEDs, further avoiding the dispersion phenomenon of the LED pixel unit, and avoiding the color difference of the LED pixel unit at different visual angles caused by the dispersion phenomenon.

### BRIEF DESCRIPTION OF DRAWINGS

In order to explain technical solutions of the embodiments of the disclosure more clearly, the following drawings required in the embodiments will be briefly introduced. It should be understood that the following drawings only illustrate some of the embodiments of the disclosure, and therefore should not be regarded as limiting the scope. For those skilled in the art, other related drawings can be obtained according to these drawings without creative labor.

FIG. 1 illustrates a schematic structural view of a display device in the related art.

FIG. 2 illustrates a schematic structural view of a LED pixel unit according to an embodiment of the disclosure.

FIG. 3 illustrates a schematic structural view of a LED pixel unit according to an embodiment of the disclosure.

FIG. 4 illustrates a schematic structural view of a LED pixel unit according to an embodiment of the disclosure.

FIG. 5 illustrates a schematic structural view of a LED pixel unit according to an embodiment of the disclosure.

FIG. 6 illustrates a schematic view of light emitted by a LED pixel unit according to an embodiment of the disclosure.

FIG. 7 illustrates a schematic structural view of a display panel according to an embodiment of the disclosure.

FIG. 8 illustrates a schematic structural view of a display panel according to an embodiment of the disclosure.

FIG. 9 illustrates a schematic structural view of a display panel according to an embodiment of the disclosure.

FIG. 10 illustrates a schematic structural view of a display panel according to an embodiment of the disclosure.

FIG. 11 illustrates a schematic structural view of a display screen used for a vehicle display screen according to an embodiment of the disclosure.

### DESCRIPTION OF REFERENCE NUMERALS

1 substrate
2 micro-LED
3 optical module
10 micro-LED
11 first micro-LED
12 second micro-LED
13 third micro-LED
20 optical module
30 partition
100 substrate
200 pixel unit
300 partition
S1 display screen

### DETAILED DESCRIPTION OF EMBODIMENTS

The following are specific embodiments to illustrate the implementation methods of the disclosure. Those skilled in the art can easily understand the other advantages and benefits of the disclosure from the content disclosed in the disclosure. The disclosure can also be implemented or operated through different specific implementation methods, and the details in the disclosure can also be modified or changed based on different perspectives and applications without departing from the spirit of the disclosure.

In the description of the disclosure, it should be noted that directions or positional relationships indicated by terms “up” and “down” are based on directions or positional relationships shown in the attached drawings, or the directions or positional relationships commonly placed during the use of the product of the disclosure. These terms are only for the convenience of describing the disclosure and simplifying the description, and do not indicate or imply that the device or component referred to must have a specific direction, be constructed and operated in a specific direction, thus they cannot be understood as a limitation on the disclosure. In addition, the terms “first” and “second” are only used to distinguish descriptions and cannot be understood as indicating or implying relative importance. It should also be understood that when a certain layer is referred to as “located on another layer or a substrate”, it can be directly located on another layer or the substrate, or there can also be an intermediate layer.

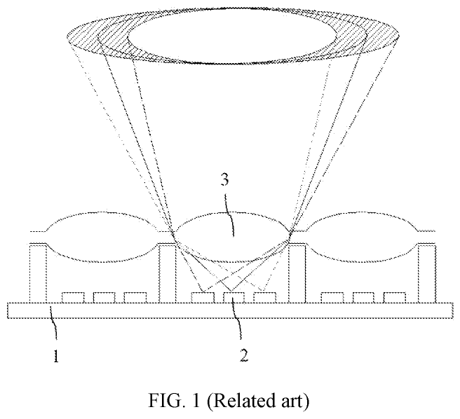

FIG. 1 illustrates a schematic structural diagram of a display device in the related art, which includes a substrate 1 and multiple pixel units disposed on the substrate 1, and each pixel unit includes multiple micro-LEDs 2, for example, each pixel unit includes three types of red micro-LED, green micro-LED and blue micro-LED. The micro-LEDs 2 are disposed on an upper surface of the substrate 1 at intervals, that is, an arrangement direction or a layout direction of the micro-LEDs 2 is parallel to the upper surface of the substrate 1.

When the display device is applied to a projection product with small light-emitting angle or a display product with small visual angle, it is necessary to provide an optical module 3 on sides of the micro-LEDs 2 facing away from the substrate 1, and the optical module 3 can adjust light emitted by the micro-LEDs 2 and light-emitting angles of each pixel unit and the display device. However, because the micro-LEDs 2 are horizontally laid on the upper surface of the substrate 1, emission angles of the light emitted by different micro-LEDs 2 are inconsistent, that is to say, the light emitted by the different micro-LEDs 2 are incident on the optical module 3 at different angles, so that only some light emitted by the micro-LEDs 2 are mixed, which is easy to cause a dispersion phenomenon, and a displayed image has color difference at different visual angles. If the micro-LEDs 2 illustrated in FIG. 1 are red, green and blue LEDs sequentially from left to right, the light emitted by the red LED is more to the right, and the light emitted by the blue LED is more to the left, which leads to the display color in a right area of the same pixel unit being more red or yellow, while the display color in a left area is more blue, and the color consistency is poor.

In order to solve the above problems, inventors stacked multiple micro-LEDs in the same pixel unit to form a stacked structure, and an optical module is disposed at a light-emitting surface of the stacked structure, which can reduce the color difference of light emitted by the micro-LEDs and effectively avoid the color difference existing in the pixel unit.

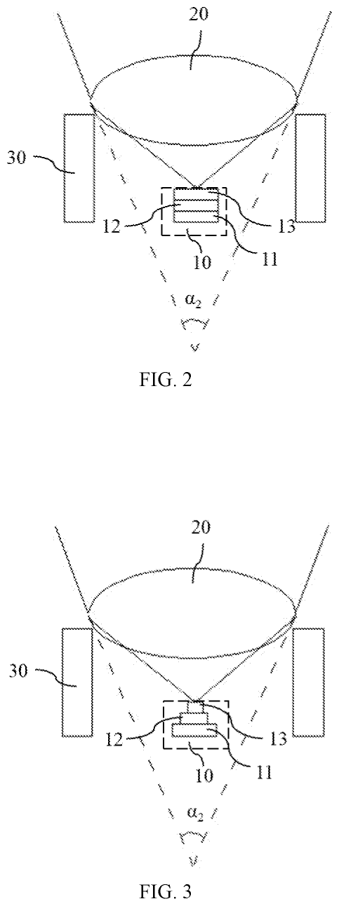

According to one aspect of the disclosure, a LED pixel unit is provided. Referring to FIG. 2, the LED pixel unit includes multiple micro-LEDs 10 and an optical module 20. Each micro-LED 10 has a length and a width of 1 μm to 100 μm. The micro-LEDs 10 with different emission wavelengths are sequentially stacked from bottom to top to form a stacked structure, and the stacked structure has a light-emitting surface, which is specifically an upper surface of the stacked structure. The stacked structure is configured to make light emitted by the micro-LEDs 10 all emit from the light-emitting surface at a first emission angle. The optical module 20 is disposed above the light-emitting surface with a predetermined distance from the light-emitting surface, a projection area of a vertical projection of the optical module 20 is greater than or equal to a projection area of a vertical projection of the stacked structure, and the vertical projection refers to a projection in a projection direction parallel to a stacking direction. The optical module 20 is configured to receive the light emitted by the light-emitting surface, and emit the light at a second emission angle, which is a light-emitting angle α₂ of the LED pixel unit. In this embodiment, the light-emitting angle α₂ of the LED pixel unit is preferably less than or equal to 80°.

A sidewall of the stacked structure formed by the micro-LEDs 10 is covered with a light shielding layer, and a material of the light shielding layer includes but is not limited to black glue, which is formed by dispersing black dye molecules or nano carbon particles in epoxy resin, acrylic or silica gel. In this embodiment, micro-LEDs 10 each can be driven independently.

In the same LED pixel unit, by stacking the micro-LEDs 10 in sequence and forming the stacked structure, light emitted by the micro-LEDs 10 can all be emitted from the same light-emitting surface, so as to reduce a difference of the light emitted by the micro-LEDs 10 and ensure the consistency of the light emitted by the micro-LEDs 10 as much as possible. The light emitted by the micro-LEDs 10 is incident on the optical module 20 at the same angle and emitted from the optical module 20 at the same angle, so that the dispersion phenomenon of the LED pixel unit can be avoided, and the problem that the LED pixel unit has color difference at different visual angles due to the dispersion phenomenon can be avoided, and the effect is particularly obvious for LED pixel units with small light-emitting angles.

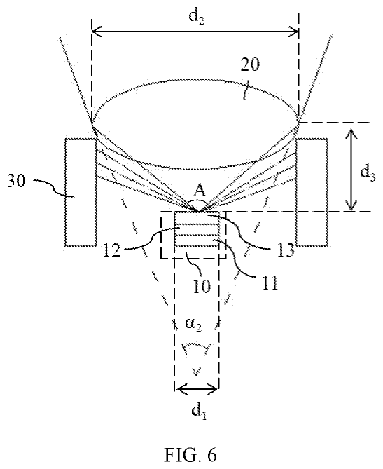

In an embodiment, referring to FIG. 6, a width of the stacked structure is d₁, a width of the optical module 20 is d₂, a distance between the optical module 20 and the light-emitting surface is d₃, and the first emission angle is A; and

$${d}_{1} \leq {d}_{2} \leq 2 {d}_{3} tan \frac{A}{2} .$$

The width d₂ of the optical module 20 must be greater than or equal to the width d₁ of the stacked structure, which is determined by the effect of the optical module 20 on the light emitted by the stacked structure. Meanwhile, in order to avoid interference between adjacent LED pixel units, the width d₂ of the optical module 20 should be less than or equal to that of the LED pixel unit.

Similarly, a length of the stacked structure is I₁, and a length of the optical module 20 is I₂, and

$${l}_{1} \leq {l}_{2} \leq 2 {d}_{3} tan \frac{A}{2} ,$$

The length I₂ of the optical module 20 must be greater than or equal to the length I₁ of the stacked structure, which is determined by the effect of the optical module 20 on the light emitted by the stacked structure. Meanwhile, in order to avoid interference between adjacent LED pixel units, the length I₂ of the optical module 20 needs to be less than or equal to the length of the LED pixel unit.

Preferably, an edge of the LED pixel unit is provided with a partition 30. Under a blocking effect of the partition 30, the first emission angle A is preferably less than or equal to 130°, that is, an angle of the light reaching the optical module 20 is preferably less than or equal to 130°. Bring A≤130° into

$${d}_{1} \leq {d}_{2} \leq 2 {d}_{3} tan \frac{A}{2} , or {l}_{1} \leq {l}_{2} \leq 2 {d}_{3} tan \frac{A}{2} ,$$

and d₁≤d₂≤4.289d₃ and I₁≤I₂≤4.289d₃ can be obtained.

In an embodiment, referring to FIGS. 2 to 5, multiple micro-LEDs 10 include a first micro-LED 11, a second micro-LED 12 and a third micro-LED 13, and the first micro-LED 11, the second micro-LED 12 and the third micro-LED 13 are sequentially stacked from bottom to top to form the above-mentioned stacked structure. An upper surface of the third micro-LED 13 is the light-emitting surface. The first micro-LED 11, the second micro-LED 12 and the third micro-LED 13 have different emission wavelengths and each are one of a red LED chip, a green LED chip and a blue LED chip. It should be noted that the number of micro-LEDs 10 is not limited to three, and the number of micro-LEDs 10 can be increased or decreased according to the actual situation.

Preferably, the first micro-LED 11 is preferably a red LED chip, the second micro-LED 12 is preferably a green LED chip, and the third micro-LED 13 is preferably a blue LED chip. It should be noted that the first, second and third micro-LEDs 11, 12 and 13 are the red LED chip, green LED chip and blue LED chip, respectively, which are only exemplary descriptions, and the types of the first, second and third micro-LEDs 11, 12 and 13 are not specifically limited in the disclosure.

Preferably, each of the first micro-LED 11, the second micro-LED 12 and the third micro-LED 13 includes a first semiconductor layer, a second semiconductor layer and an active layer disposed between the first semiconductor layer and the second semiconductor layer, the first semiconductor layer is an N-type semiconductor layer, the second semiconductor layer is a P-type semiconductor layer, and the active layer is a multi-layer quantum well layer, which can provide radiation of red light, green light or blue light. The N-type semiconductor layer, the multi-layer quantum well layer, and the P-type semiconductor layer are only the basic constituent units of the first, second, and third micro-LEDs 11, 12, and 13. On this basis, the first, second, and third micro-LEDs 11, 12, and 13 may further include other functional structural layers that can optimize the performance of micro-LEDs. It should be noted that the structures of the first micro-LED 11, the second micro-LED 12 and the third micro-LED 13 are not specifically limited in the disclosure.

Preferably, the second semiconductor layer in each micro-LED 10 is provided with a distributed Bragg reflector (DBR), and the DBR extends from the corresponding second semiconductor layer to the sidewall of each micro-LED 10. Configuring the DBR between adjacent two micro-LEDs 10 can make the DBR reflect light with a specific band and transmit light with another band. Specifically, the DBR can transmit the light generated by the micro-LED 10 with a longer wavelength and reflect the light generated by the micro-LED 10 with a shorter wavelength. The light generated by the first micro-LED 11 and the second micro-LED 12 can be emitted to the outside through the third micro-LED 13, and the DBR can reflect the light generated by the second micro-LED 12 or the third micro-LED 13 to avoid light loss and increase the light intensity.

The above DBR is made by using technologies such as electron beam evaporation or ion beam sputtering to alternately stack multiple materials with different refractive indices into multiple layers. The materials of the DBR are preferably at least two different materials such as silicon dioxide (SiO₂), titanium dioxide (TiO₂), titanium dioxide (ZnO₂), zirconium dioxide (ZrO₂), copper sesquioxide (Cu₂O₃), aluminum trioxide (Al₂O₃), etc.

In an embodiment, referring to FIG. 2, projection areas of vertical projections of the micro-LEDs 10 are equal, and the micro-LEDs 10 have the same light-emitting axes. The light-emitting axes of the micro-LEDs 10 are coincident with a light-emitting axis of the stacked structure, which can ensure the consistency of the light emitted by the micro-LEDs 10, further avoid the dispersion phenomenon of the LED pixel unit, and avoid the problem of color difference at different visual angels in the LED pixel unit caused by the dispersion phenomenon.

As an alternative embodiment, referring to FIG. 3, projection areas of vertical projections of the micro-LEDs 10 are decreased and the micro-LEDs 10 have same light-emitting axes. The light-emitting axes of the micro-LEDs 10 are coincident with a light-emitting axis of the stacked structure, which can ensure the consistency of the light emitted by the micro-LEDs 10, further avoid the dispersion phenomenon of the LED pixel unit, and avoid the problem of color difference at different visual angels in the LED pixel unit caused by the dispersion phenomenon. Specifically, projection areas of vertical projections of the first micro-LED 11, the second micro-LED 12 and the third micro-LED 13 are sequentially decreased in that order. The first micro-LED 11 is a red LED chip and has the largest size, which can further improve the brightness of the first micro-LED 11 to improve the resolution of the LED pixel unit.

Preferably, a ratio of the projection areas of the first micro-LED 11 and the third micro-LED 13 is preferably greater than or equal to 2. A ratio of the projection areas of the second micro-LED 12 and the third micro-LED 13 is preferably greater than or equal to 1.5 and less than or equal to 3. In this embodiment, a ratio of the projection areas of the first micro-LED 11, the second micro-LED 12 and the third micro-LED 13 may be 10:7:3 or 10:6:4.

Preferably, a ratio of a covered area to an uncovered area of the second micro-LED 12 on the first micro-LED 11 is greater than or equal to 1.5 and less than or equal to 3. The ratio of the covered area to the uncovered area of the second micro-LED 12 on the first micro-LED 11 is preferably 1.5.

Preferably, a ratio of a covered area to an uncovered area of the third micro-LED 13 on the second micro-LED 12 is greater than or equal to 0.5 and less than or equal to 2. The ratio of the covered area to the uncovered area of the third micro-LED 13 on the second micro-LED 12 is preferably 2.

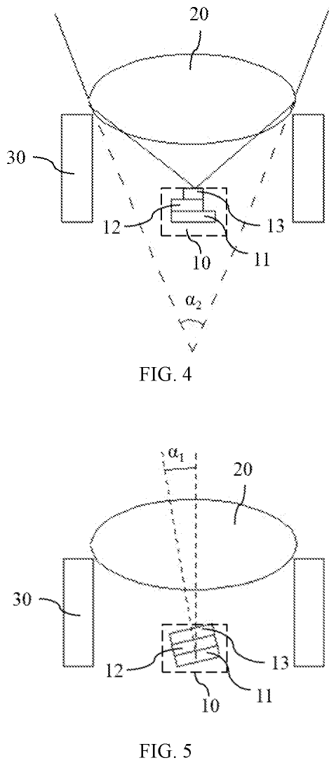

As an alternative embodiment, referring to FIG. 4, projection areas of vertical projections of the micro-LEDs 10 are decreased, and a light-emitting axis of the micro-LED at a side of the stacked structure facing from the light-emitting surface is coincident with a light-emitting axis of the micro-LED 10 at a side of the stacked structure proximate to the light-emitting surface. In this embodiment, the first micro-LED 11 has the largest projection area, and the light-emitting axes of the first micro-LED 11 and the third micro-LED 13 are coincident.

In an embodiment, referring to FIGS. 2 and 3, the micro-LEDs 10 have the same light-emitting axes, and the light-emitting axes of the micro-LEDs 10 are coincident with a light-emitting axis of the stacked structure. A central axis of the optical module 20 is preferably coincident with the light-emitting axes of the micro-LEDs 10, that is, the central axis of the optical module 20 is preferably coincident with the light-emitting axis of the stacked structure.

As an alternative embodiment, referring to FIG. 4, the light-emitting axes of some micro-LEDs 10 are different. The central axis of the optical module 20 is preferably coincident with the light-emitting axis of the micro-LED 10 at the side of the stacked structure proximate to the light-emitting surface. In this embodiment, the central axis of the optical module 20 is preferably coincident with the light-emitting axis of the third micro-LED 13.

As an alternative embodiment, referring to FIG. 5, the micro-LEDs 10 have the same light-emitting axes, and the light-emitting axes of the micro-LEDs 10 are coincident with the light-emitting axis of the stacked structure. An angle α₁ between the central axis of the optical module 20 and the light-emitting axis of the stacked structure is preferably greater than 5°, that is, the angle α₁ between the central axis of the optical module 20 and the light-emitting axes of the micro-LEDs 10 is preferably greater than 5°. At this time, the projection areas of the vertical projections of the micro-LEDs 10 are equal, or the projection areas of the vertical projections of the micro-LEDs 10 are decreased.

As an alternative embodiment, the light-emitting axes of some micro-LEDs 10 are different. An angle between the central axis of the optical module 20 and the light-emitting axes of the micro-LEDs 10 is preferably greater than 5°. At this time, the projection areas of the vertical projections of the micro-LEDs 10 are decreased.

In an embodiment, the optical module 20 includes a micro lens, a micro prism or a micro mirror. The micro lens includes, but is not limited to, a Fresnel lens, a diffusion lens, a convex lens and a concave lens. The micro mirror includes, but is not limited to, a concave mirror and a convex mirror. The optical module 20 is used to adjust the light emitted by the stacked structure and change the emission path of the light, so as to reduce, enlarge or change the emission angle of the light emitted by the stacked structure. For example, the optical module 20 is preferably a convex lens, and the emission angle A of the light emitted by the stacked structure is 130°. After passing through the optical module 20, the emission angle of the light emitted by the stacked structure is reduced to 80°, that is, the light-emitting angle α₂ of the LED pixel unit is 80°.

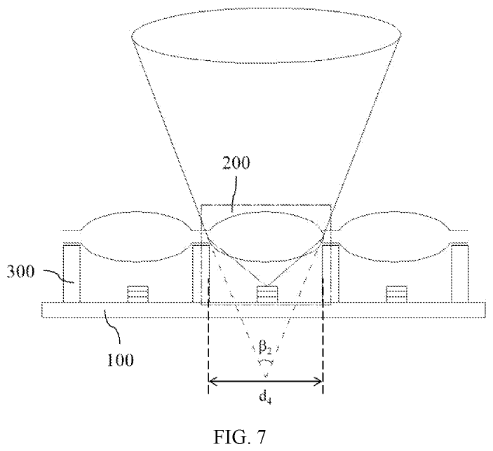

According to one aspect of the disclosure, a display panel is provided. Referring to FIGS. 7 to 10, the display device includes a substrate 100 and multiple pixel units 200 disposed on the substrate 100, and each pixel unit 200 is the LED pixel unit in the above embodiments. A material of the substrate 100 includes, but is not limited to, glass, quartz, silicon, sapphire, organic polymer or organic-inorganic composite material, and a surface of the substrate 100 on which the pixel units 200 are disposed is further provided with a circuit part and a driving part to apply light-emitting signals and control voltages to the pixel units 200.

Referring to FIGS. 2 to 5, each pixel unit 200 includes multiple micro-LEDs 10 and an optical module 20. Each micro-LED 10 has a length and a width of 1 μm to 100 μm. The micro-LEDs 10 with different emission wavelengths are sequentially stacked from bottom to top to form a stacked structure. The stacked structure is disposed on the substrate 100, a side surface of the stacked structure facing away from the substrate 100 is a light-emitting surface, and the light-emitting surface is specifically an upper surface of the stacked structure. The stacked structure is configured to make light emitted by the micro-LEDs 10 all be emitted from the light-emitting surface at a first emission angle. The optical module 20 is disposed above a side of the stacked structure facing away from the substate 100 with a predetermined distance from the light-emitting surface, a projection area of a vertical projection of the optical module 20 is greater than or equal to a projection area of a vertical projection of the stacked structure, and the vertical projection refers to a projection in a projection direction parallel to a stacking direction. The optical module 20 is configured to receive the light emitted by the light-emitting surface, and emit the light emitted by the light-emitting surface at a second emission angle, the second emission angle is a light-emitting angle β₂ of the pixel unit 200 and the display panel. In this embodiment, the light-emitting angle β₂ of the pixel unit 200 and display panel is preferably less than or equal to 80°.

A sidewall of the stacked structure formed by the micro-LEDs 10 is covered with a light shielding layer, and a material of the light shielding layer includes but is not limited to black glue, which is formed by dispersing black dye molecules or nano carbon particles in epoxy resin, acrylic or silica gel. In this embodiment, each micro-LED 10 can be driven independently.

In the same pixel unit 200, by stacking the micro-LEDs 10 in sequence and forming the stacked structure, light emitted by the micro-LEDs 10 can all be emitted from the same light-emitting surface, so as to reduce a difference of the light emitted by the micro-LEDs 10 and ensure the consistency of the light emitted by the micro-LEDs 10 as much as possible. The light emitted by the micro-LEDs 10 is incident on the optical module 20 at the same angle and emitted from the optical module 20 at the same angle, so that the dispersion phenomenon of the pixel unit 200 can be avoided, and the problem of color difference at different visual angles in the pixel unit 200 caused by the dispersion phenomenon can be avoided, which is particularly obvious for the pixel unit 200 or the display panel with small light-emitting angle.

In an embodiment, referring to FIGS. 6 to 10, a width of the stacked structure is d₁, a width of the optical module 20 is d₂, a distance between the optical module 20 and the light-emitting surface is d₃, a width of the pixel unit 200 is d₄, a first emission angle is A, and

$${d}_{1} \leq {d}_{2} \leq 2 {d}_{3} tan \frac{A}{2} ,$$

and d₁≤d₂≤d₄. The width d₂ of the optical module 20 must be greater than or equal to the width d₁ of the stacked structure, which is determined by the effect of the optical module 20 on the light emitted by the stacked structure. Meanwhile, in order to avoid interference between adjacent pixel units 200, the width d₂ of the optical module 20 should be less than or equal to the width d₄ of the pixel unit 200.

Similarly, a length of the stacked structure is I₁, a length of the optical module 20 is I₂, a width of the pixel unit 200 is d₄,

$${l}_{1} \leq {l}_{2} \leq 2 {d}_{3} tan \frac{A}{2} ,$$

and d₁≤d₂≤d₄. The length I₂ of the optical module 20 must be greater than or equal to the length I₁ of the stacked structure, which is determined by the effect of the optical module 20 on the light emitted by the stacked structure. Meanwhile, in order to avoid interference between adjacent pixel units 200, the length I₂ of the optical module 20 needs to be less than or equal to the length I₄ of the pixel unit 200.

Preferably, the adjacent pixel units 200 are separated by a partition 300. Under a blocking effect of the partition 300, the first emission angle A in each pixel unit 200 is preferably less than or equal to 130°, that is, an angle of the light reaching the optical module 20 is preferably less than or equal to 130°. Bring A ≤130° into

$${d}_{1} \leq {d}_{2} \leq 2 {d}_{3} tan \frac{A}{2} , or {l}_{1} \leq {l}_{2} \leq 2 {d}_{3} tan \frac{A}{2} ,$$

and d₁≤d₂≤4.289d₃ and I₁≤I₂≤4.289d₃ can be obtained.

In an embodiment, referring to FIGS. 2 to 5, in the same pixel unit 200, multiple micro-LEDs 10 include a first micro-LED 11, a second micro-LED 12 and a third micro-LED 13, and the first micro-LED 11, the second micro-LED 12 and the third micro-LED 13 are sequentially stacked from bottom to top to form the above-mentioned stacked structure. The first micro-LED 11 is disposed at a side of the stacked structure proximate to the substrate 100, and an upper surface of the third micro-LED 13 is the light-emitting surface. The first micro-LED 11, the second micro-LED 12 and the third micro-LED 13 have different emission wavelengths and each are one of a red LED chip, a green LED chip and a blue LED chip. It should be noted that the number of micro-LEDs 10 is not limited to three, and the number of micro-LEDs 10 can be increased or decreased according to the actual situation.

Preferably, the first micro-LED 11 is preferably a red LED chip, the second micro-LED 12 is preferably a green LED chip, and the third micro-LED 13 is preferably a blue LED chip. It should be noted that the first, second and third micro-LEDs 11, 12 and 13 are the red LED chip, green LED chip and blue LED chip, respectively, which are only exemplary descriptions, and the types of the first, second and third micro-LEDs 11, 12 and 13 are not specifically limited in the disclosure.

Preferably, each of the first micro-LED 11, the second micro-LED 12 and the third micro-LED 13 includes a first semiconductor layer, a second semiconductor layer and an active layer disposed between the first semiconductor layer and the second semiconductor layer, the first semiconductor layer is an N-type semiconductor layer, the second semiconductor layer is a P-type semiconductor layer, and the active layer is a multi-layer quantum well layer, which can provide radiation of red light, green light or blue light. The N-type semiconductor layer, the multi-layer quantum well layer, and the P-type semiconductor layer are only the basic constituent units of the first, second, and third micro-LEDs 11, 12, and 13. On this basis, the first, second, and third micro-LEDs 11, 12, and 13 may further include other functional structural layers that can optimize the performance of micro-LEDs. It should be noted that the structures of the first micro-LED 11, the second micro-LED 12 and the third micro-LED 13 are not specifically limited in the disclosure.

Preferably, the second semiconductor layer in each micro-LED 10 is provided with a distributed Bragg reflector (DBR), and the DBR extends from the corresponding second semiconductor layer to the sidewall of each micro-LED 10. Configuring the DBR between adjacent two micro-LEDs 10 can make the DBR reflect light with a specific band and transmit light with another band. Specifically, the DBR can transmit the light generated by the micro-LED 10 with a longer wavelength and reflect the light generated by the micro-LED 10 with a shorter wavelength. The light generated by the first micro-LED 11 and the second micro-LED 12 can be emitted to the outside through the third micro-LED 13, and the DBR can reflect the light generated by the second micro-LED 12 or the third micro-LED 13 to avoid light loss and increase the light intensity.

The above DBR is made by using technologies such as electron beam evaporation or ion beam sputtering to alternately stack multiple materials with different refractive indices into multiple layers. The materials of the DBR are preferably at least two different materials such as SiO₂, TiO₂, ZnO₂, ZrO₂, Cu₂O₃, Al₂O₃, etc.

In an embodiment, referring to FIG. 2 and FIG. 7, in the same pixel unit 200, projection areas of vertical projections of the micro-LEDs 10 are equal, and the micro-LEDs 10 have the same light-emitting axes. The light-emitting axes of the micro-LEDs 10 are coincident with a light-emitting axis of the stacked structure, which can ensure the consistency of the light emitted by the micro-LEDs 10, further avoid the dispersion phenomenon of the pixel unit 200, and avoid the problem of color difference at different visual angels in the pixel unit 200 caused by the dispersion phenomenon.

Preferably, the central axis of the optical module 20 is preferably coincident with the light-emitting axis of the stacked structure, and both the central axis of the optical module 20 and the light-emitting axis of the stacked structure are perpendicular to the substrate 100.

Alternatively, referring to FIGS. 5 and 10, an angle between the central axis of the optical module 20 and the light-emitting axis of the stacked structure is preferably greater than 5°. The central axis of the optical module 20 is perpendicular to the substrate 100, and the angle β₁ between the stacked structure and the substrate 100 is preferably greater than 5°.

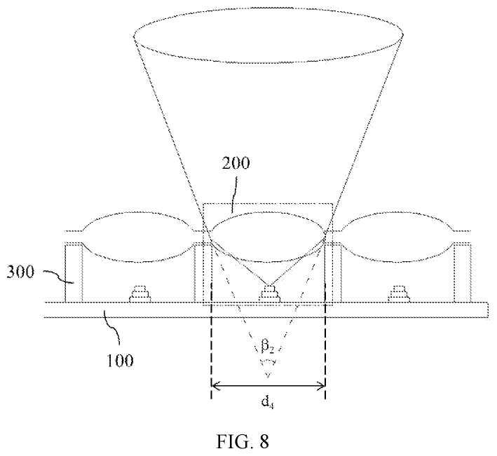

As an alternative embodiment, referring to FIGS. 3 and 8, in the same pixel unit 200, projection areas of vertical projections of the micro-LEDs 10 are decreased, and the micro-LEDs 10 have same light-emitting axes. The light-emitting axes of the micro-LEDs 10 are coincident with the light-emitting axis of the stacked structure, which can ensure the consistency of the light emitted by the micro-LEDs 10, further avoid the dispersion phenomenon of the pixel unit 200, and avoid the problem of color difference at different visual angels in the pixel unit 200 caused by the dispersion phenomenon. Specifically, projection areas of vertical projections of the first micro-LED 11, the second micro-LED 12 and the third micro-LED 13 are decreased sequentially in that order. The first micro-LED 11 is a red LED chip and has the largest size, which can further improve the brightness of the first micro-LED 11 to improve the resolution of the pixel unit 200 and the display panel.

Preferably, a ratio of the projection areas of the first micro-LED 11 and the third micro-LED 13 is preferably greater than or equal to 2. A ratio of the projection areas of the second micro-LED 12 and the third micro-LED 13 is preferably greater than or equal to 1.5 and less than or equal to 3. In this embodiment, a ratio of the projection areas of the first micro-LED 11, the second micro-LED 12 and the third micro-LED 13 may be 10:7:3 or 10:6:4.

Preferably, a ratio of a covered area to an uncovered area of the second micro-LED 12 on the first micro-LED 11 is greater than or equal to 1.5 and less than or equal to 3. The ratio of the covered area to the uncovered area of the second micro-LED 12 on the first micro-LED 11 is preferably 1.5.

Preferably, a ratio of a covered area to an uncovered area of the third micro-LED 13 on the second micro-LED 12 is greater than or equal to 0.5 and less than or equal to 2. The ratio of the covered area to the uncovered area of the third micro-LED 13 on the second micro-LED 12 is preferably 2.

Preferably, the central axis of the optical module 20 is preferably coincident with the light-emitting axis of the stacked structure, and both the central axis of the optical module 20 and the light-emitting axis of the stacked structure are perpendicular to the substrate 100.

Alternatively, an angle between the central axis of the optical module 20 and the light-emitting axis of the stacked structure is preferably greater than 5°. The central axis of the optical module 20 is perpendicular to the substrate 100, and the angle β₁ between the stacked structure and the substrate 100 is preferably greater than 5°.

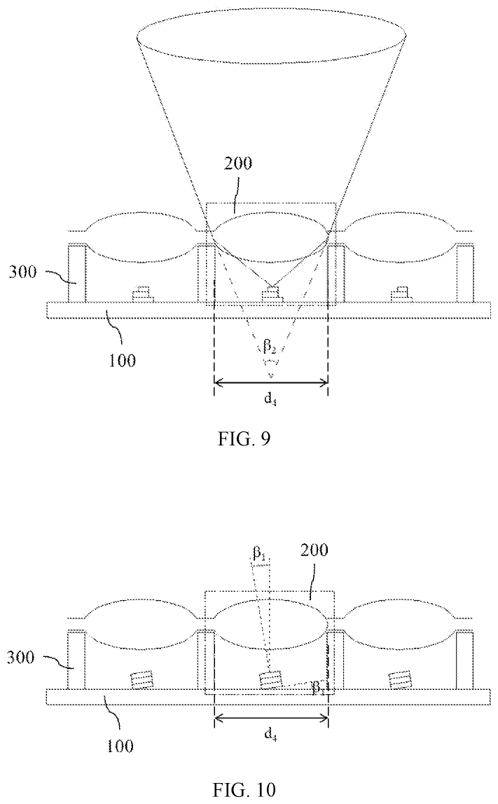

As an alternative embodiment, referring to FIGS. 4 and 9, in the same pixel unit 200, projection areas of vertical projections of the micro-LEDs 10 are decreased, and the light-emitting axis of the micro-LED at a side of the stacked structure facing away from the light-emitting surface is coincident with the light-emitting axis of the micro-LED 10 at a side of the stacked structure proximate to the light-emitting surface. In this embodiment, the first micro-LED 11 has the largest projection area, and the light-emitting axes of the first micro-LED 11 and the third micro-LED 13 are coincident.

Preferably, the light-emitting axes of some micro-LEDs 10 are different, and the light-emitting axes of the micro-LEDs 10 are parallel to each other. The central axis of the optical module 20 and the light-emitting axis of each micro-LED 10 are perpendicular to the substrate 100. The central axis of the optical module 20 is preferably coincident with the light-emitting axis of the micro-LED 10 at the side of the stacked structure proximate to the light-emitting surface and the light-emitting axis of the micro-LED 10 at the side of the stacked structure facing away from the light-emitting surface. In this embodiment, the central axis of the optical module 20 is preferably coincident with the light-emitting axes of the first micro-LED 11 and the third micro-LED 13.

Alternatively, an angle between the central axis of the optical module 20 and the light-emitting axis of the stacked structure is preferably greater than 5°. The central axis of the optical module 20 is perpendicular to the substrate 100, and the angle β₁ between the stacked structure and the substrate 100 is preferably greater than 5°.

In an embodiment, the optical module 20 in each pixel unit 200 includes a micro lens, a micro prism or a micro mirror. The micro lens includes, but is not limited to, a Fresnel lens, a diffusion lens, a convex lens and a concave lens. The micro mirror includes, but is not limited to, a concave mirror and a convex mirror. The optical module 20 is used to adjust the light emitted by the stacked structure and change the emission path of the light, so as to reduce, enlarge or change the emission angle of the light emitted by the stacked structure. For example, the optical module 20 is preferably the convex lens, and the emission angle A of the light emitted by the stacked structure is 130°. After passing through the optical module 20, the emission angle of the light emitted by the stacked structure is reduced to 80°, that is, the light-emitting angle β₂ of the pixel unit 200 and the display panel is 80°. The optical modules 20 in all the pixel units 200 constitute a micro lens array, a micro prism array or a micro mirror array.

To sum up, the display panel in the embodiment is not only suitable for the case that the light-emitting angle is less than or equal to 80°, but also suitable for the case that the stacked structure is offset on the substrate 100, that is, the angle between the light-emitting axis of the stacked structure and the substrate 100 is greater than 5°. In the above two cases, by sequentially stacking the micro-LEDs 10 in the same pixel unit 200 to form the stacked structure, it can reduce the difference of light emitted by the micro-LEDs 10, and ensure the consistency of light emitted by the micro-LEDs 10 as much as possible, thereby avoiding the dispersion phenomenon of the pixel unit 200 and the display panel, and avoiding the problem of color difference.

According to an aspect of the disclosure, a display screen which the display panel in the above embodiment is applied is provided.

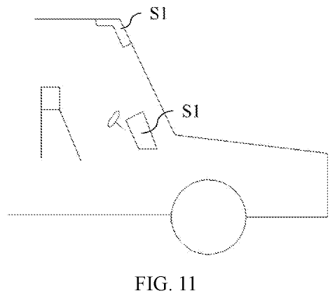

As shown in FIG. 11, FIG. 11 illustrates an application scene of a display screen S1 used for a vehicle display screen, and the display screen S1 can be disposed at any position within the visual field observed by a driver in a car. Usually, when the driver in the car observes the display screen S1, it is not facing the display screen S1, and there is an off-angle or small-angle visual angle. At the same time, passengers in the car also need to observe the display screen S1 from different angles. By using the display screen S1 in the disclosure, the color difference caused by the dispersion phenomenon can be well avoided, and the display screen S1 has good color consistency at different visual angles, which brings better viewing experience to people in the car. In addition, the display screen S1 can also be disposed on a roof, because there is no color difference, even if the driver observes the display screen S1 at a very small angle, better viewing effect can still be obtained.

According to the above technical solutions, the micro-LEDs 10 in the same LED pixel unit are stacked to form the stacked structure, so that the light emitted by the micro-LEDs 10 can all be emitted from the same light-emitting surface, incident on the optical module 20 at the same angle, and emitted from the optical module 20 at the same angle, which can avoid the dispersion phenomenon of the LED pixel unit, and avoid the problem of color difference at different visual angles in the LED pixel unit due to the dispersion phenomenon, and the effect is particularly obvious for LED pixel units with small light-emitting angles.

Furemore, the width of the stacked structure is d₁, the width of the optical module 20 is d₂, the distance between the optical module 20 and the light-emitting surface is d₃, and the first emission angle is A, and d₁≤d₂≤2d₃ tan A/2, thereby making the optical module 20 cover the whole emission range of the light emitted by the stacked structure, so as to adjust all light emitted by the stacked structure and make the light-emitting angle of the LED pixel unit less than or equal to 80°.

Furemore, the micro-LEDs 10 have the same light-emitting axes, and the light-emitting axes of the micro-LEDs 10 are coincident with the light-emitting axis of the stacked structure, so that the consistency of light emitted by the micro-LEDs 10 can be ensured, and the dispersion phenomenon of LED pixel units can be further avoided, and the problem of color difference at different visual angles in the LED pixel unit caused by the dispersion phenomenon can be avoided.

The above are only the preferred embodiments of the disclosure. It should be pointed out that for those skilled in the art, several improvements and replacements can be made without departing from the technical principles of the disclosure. These improvements and replacements should also be considered as the scope of protection of the disclosure.

What is claimed is:

1. A light-emitting diode (LED) pixel unit, comprising:
a plurality of micro light-emitting diodes (micro-LEDs) with different emission wavelengths, stacked to form a stacked structure; wherein the stacked structure has a light-emitting surface, and the stacked structure is configured to emit, from the light-emitting surface, light emitted by the plurality of micro-LEDs at a first emission angle; and
an optical module, disposed above the light-emitting surface and at a predetermined distance from the light-emitting surface; wherein a projection area of a vertical projection of the optical module is greater than or equal to a projection area of a vertical projection of the stacked structure; and the optical module is configured to emit, at a second emission angle, the light emitted by the light-emitting surface.

2. The LED pixel unit as claimed in claim 1, wherein a width of the stacked structure is d₁, a width of the optical module is d₂, the predetermined distance between the optical module and the light-emitting surface is d₃, and the first emission angle is A; and
$$wherein {d}_{1} \leq {d}_{2} \leq 2 {d}_{3} tan \frac{A}{2} , A \leq 130 ° .$$

3. The LED pixel unit as claimed in claim 1, wherein projection areas of vertical projections of the plurality of micro-LEDs are equal, and the plurality of micro-LEDs have same light-emitting axes.

4. The LED pixel unit as claimed in claim 1, wherein projection areas of vertical projections of the plurality of micro-LEDs are decreased, and the plurality of micro-LEDs have same light-emitting axes.

5. The LED pixel unit as claimed in claim 1, wherein projection areas of vertical projections of the plurality of micro-LEDs are decreased, and a light-emitting axis of the micro-LED at a side of the stacked structure facing away from the light-emitting surface coincides with a light-emitting axis of the micro-LED at a side of the stacked structure proximate to the light-emitting surface.

6. The LED pixel unit as claimed in claim 3, wherein a central axis of the optical module coincides with the light-emitting axes of the plurality of micro-LEDs.

7. The LED pixel unit as claimed in claim 4, wherein a central axis of the optical module coincides with the light-emitting axes of the plurality of micro-LEDs.

8. The LED pixel unit as claimed in claim 5, wherein a central axis of the optical module coincides with the light-emitting axis of the micro-LED at the side of the stacked structure proximate to the light-emitting surface.

9. The LED pixel unit as claimed in claim 1, wherein an angle al between a central axis of the optical module and light-emitting axes of the plurality of micro-LEDs is greater than 5°.

10. The LED pixel unit as claimed in claim 9, wherein the light-emitting axes of the plurality of micro-LEDs are the same.

11. The LED pixel unit as claimed in claim 1, wherein a light-emitting angle α₂ of the LED pixel unit is less than or equal to 80°.

12. The LED pixel unit as claimed in claim 1, wherein the stacked structure comprises, from bottom to top, a red LED chip, a green LED chip, and a blue LED chip.

13. A display panel, comprising:
a substrate; and
a plurality of pixel units, disposed on the substrate; wherein each of the plurality of pixel units is the LED pixel unit as claimed in claim 1, the stacked structure of the LED pixel unit is disposed on the substrate, and the optical module of the LED pixel unit is disposed at a side of the stacked structure facing away from the substrate.

14. The display panel as claimed in claim 13, wherein a width of the stacked structure is d₁, a width of the optical module is d₂, the predetermined distance between the optical module and the light-emitting surface is d₃, and the first emission angle is A; and
$${d}_{1} \leq {d}_{2} \leq 2 {d}_{3} tan \frac{A}{2} , A \leq 130 ° .$$

15. The display panel as claimed in claim 14, wherein a width of each of the plurality of pixel units is d₄, and d₁≤d₂≤d₄.

16. The display panel as claimed in claim 13, wherein a central axis of the optical module is perpendicular to the substrate, and an angle between the stacked structure and the substrate is β₁, which is greater than 5°.

17. The display panel as claimed in claim 13, wherein a central axis of the optical module and a light-emitting axis of the stacked structure are both perpendicular to the substrate.

18. The display panel as claimed in claim 13, wherein the plurality of micro-LEDs have same light-emitting axes, and an angle α₁ between a central axis of the optical module and the light-emitting axis of each of the plurality of micro-LEDs is greater than 5°.

19. The display panel as claimed in claim 13, wherein a central axis of the optical module coincides with light-emitting axes of at least two of the plurality of micro-LEDs.

20. A display screen, comprising: the display panel as claimed in claim 13.
